(19) United States
(12) Patent Application Publication
(10) Pub. No.: US 2017/0212280 A1
(43) Pub. Date: Jul. 27, 2017

(54) PRODUCTION OF A THIN FILM REFLECTOR

(71) Applicant: SCINT-X AB, Kista (SE)

(72) Inventors: Anna SAHLHOLM, Huddinge (SE); Tapani ALASAARELA, Helsinki (FI)

(21) Appl. No.: 15/324,358

(22) PCT Filed: May 19, 2015
(86) PCT No.: PCT/SE2015/050564

§ 371 Date: Jan. 6, 2017

Related U.S. Application Data
(60) Provisional application No. 62/021,356, filed on Jul. 7, 2014.

(51) Int. Cl. G02B 1/14; G02B 5/08; C23C 16/455; C23C 16/52; C23C 16/02; C23C 16/40

(52) U.S. Cl. CPC G02B 1/14; C23C 16/0272; C23C 16/40; C23C 16/45527; C23C 16/52; G02B 5/085; G02B 5/0808

(57) ABSTRACT

There is provided a thin film reflector, a method and an ALD-system for producing the thin film reflector. The method includes the steps of providing a substrate including at least one type of material, and providing a thin film including a metallic compound on at least part of the substrate. The method also includes the step of coating at least part of the thin film with a first barrier layer by applying Low Temperature Atomic Layer Deposition with at least one first material, and the step of providing a second barrier layer on at least part of the first barrier layer by applying High Temperature Atomic Layer Deposition, with at least one second material to thereby obtain a multi-layered thin film reflector. There is also an ALD control system for controlling the ALD-system. There is furthermore provided a computer program for controlling the temperature to be used by an ALD-tool.

### TECHNICAL FIELD

The proposed technology relates to a method for producing a thin film reflector, and an Atomic Layer Deposition, ALD, system for producing a thin film reflector, a control system for an ALD system, and a computer program for controlling an ALD system, as well as a thin film reflector.

### BACKGROUND

Reflectors are used in a wide range of applications, and they can be manufactured in various different ways. The reflective metal in reflector applications is usually aluminium or silver for the visible wavelength range and gold for infrared wavelengths. As the metal layers corrode and are mechanically fragile, they need some form of protection to stay reflective over time.

The two ways to produce reflectors are the first surface mirror approach and the second surface mirror approach. The second surface mirrors have a thick glass or polymer sheet on top of the metal layer to protect them mechanically. This way, the protective films on the backside of the mirror can be opaque and the reflection through the glass or polymer is used instead. The often millimeter-thick glass provides good mechanical protection against all kinds of attacks, but gives lower overall reflectivity than a first surface mirror. The highest reflectivity in the visible wavelength range can be reached with front surface silver mirrors, which rely on a thin silver coating protected with thin film barrier layers. When highly reflective microstructures are needed, there is no physical space for other than thin barrier films and the second surface mirror is not even an option.

At higher temperatures, the corrosion of metals happens more rapidly and certain metal thin films begin forming droplets. These problems usually start already at temperatures below their melting points, and result in a lower reflectivity. For these reasons, the useful temperature range for metal reflectors is usually rather limited.

### SUMMARY

It is a general object to provide a method for producing a thin film reflector.

It is also an object to provide an Atomic Layer Deposition, ALD, system for producing a thin film reflector.

Another object is to provide a control system for the ALD system.

Yet another object is to provide a computer software system for controlling an ALD system.

Still another object is to provide a thin film reflector.

These and other objects are met by embodiments of the proposed technology.

According to a first aspect, there is provided a method for producing a thin film reflector. The method comprises the steps of:
providing a substrate comprising at least one type of material;
providing a thin film including a metallic compound on at least part of the substrate;
coating at least part of the thin film with a first barrier layer by applying Low Temperature Atomic Layer Deposition, LT-ALD, with at least one first material; and
providing a second barrier layer on at least part of the first barrier layer by applying High Temperature Atomic Layer Deposition, HT-ALD, with at least one second material to thereby obtain a multi-layered thin film reflector.

According to a second aspect there is provided an Atomic Layer Deposition, ALD, system for producing a thin film reflector. The ALD system comprises:
a control system comprising one or a plurality of control subsystems, and
at least one ALD tool controlled by the control system,
   wherein an ALD tool is configured to provide a first barrier layer on at least part of a thin film including a metallic compound by applying Low Temperature ALD, LT-ALD, with at least one first material, and
   wherein an ALD tool is configured to provide a second barrier layer on at least part of the first barrier layer by applying High Temperature ALD, HT-ALD, with at least one second material, to thereby obtain a multi-layered thin film reflector.

According to a third aspect there is provided a control system configured to control an Atomic Layer Deposition, ALD, system, wherein the ALD system comprises at least one ALD tool,
wherein the control system is configured to control at least a first temperature at which an ALD tool shall apply Low Temperature ALD, LT-ALD, with at least one first material on at least part of a thin film including a metallic compound to at least partially coat the thin film with a first barrier layer, and
wherein the control system is configured to control at least a second temperature at which an ALD tool shall apply High Temperature ALD, HT-ALD, with at least one second material on at least part of the first barrier layer to at least partially coat the first barrier layer with a second barrier layer to thereby obtain a multi-layered thin film reflector.

According to a fourth aspect there is provided a computer program comprising instructions which, when executed on at least one processor, cause the at least one processor to:
control at least a first temperature at which an ALD tool shall apply Low Temperature ALD, LT-ALD, with at least one first material to coat at least part of a thin film including a metallic compound with a first barrier layer;
control at least a second temperature at which an ALD tool shall apply High Temperature ALD, HT-ALD, with at least one second material on at least part of the first barrier layer to coat at least part of the first barrier layer with a second barrier layer to thereby obtain a multi-layered thin film reflector.

According to a fifth aspect there is provided a thin film reflector comprising:
a substrate comprising at least one type of material;
a thin film of a metallic compound provided on at least part of the substrate;
a first barrier layer provided on at least part of the thin film by means of Low Temperature Atomic Layer Deposition, LT-ALD, and
a second barrier layer provided on at least part of the first barrier layer by means of High Temperature Atomic Layer Deposition, HT-ALD.

In this way, it is possible to provide a thin film reflector with excellent properties with regard to, for example, high thermal and/or chemical stability.

By way of example, a thin film reflector according to the proposed technology could be used as part of a scintillator for X-ray applications. The thin film reflector can provide improved efficiency for reflecting secondary photons in the scintillator component. A reflector with excellent heat tolerance features is needed to avoid degradation due to heat applied during the manufacturing stage of the scintillator and/or the heat impact that may arise during use of the scintillator in, for example, X-ray applications.

Other examples where a thin film reflector according to the proposed technology might be used include applications that require high temperatures or high temperature ranges such as within high-temperature lamps, as part of laser systems (e.g. for use as a laser reflector), or as part of optical or electro-optical devices (e.g. for use in space applications).

Other advantages will be appreciated when reading the detailed description.

### BRIEF DESCRIPTION OF THE DRAWINGS

The embodiments, together with further objects and advantages thereof, may best be understood by making reference to the following description taken together with the accompanying drawings, in which:

FIG. 1 discloses a schematic flow diagram illustrating an example of a method for producing a thin film reflector according to an embodiment.

FIG. 2 discloses a schematic block diagram illustrating an example of an Atomic Layer Deposition, ALD, system for producing a thin film reflector according to an embodiment.

FIG. 3 discloses a schematic block diagram illustrating an example of an ALD control system according to an embodiment.

FIG. 4 discloses a schematic example of a thin film reflector according to an embodiment.

FIG. 5A discloses a block diagram illustrating an example of a control system configured to control an Atomic Layer Deposition, ALD, system according to an embodiment of the proposed technology.

FIG. 5B illustrates an example of an implementation of a computer program according to an embodiment of the proposed technology.

FIG. 6 is a schematic block diagram illustrating an example of an ALD system according to an embodiment of the proposed technology.

FIG. 7 is a schematic block diagram illustrating an example of an alternative ALD system according to an embodiment of the proposed technology.

FIG. 8 is a schematic illustration of an example of a thin film reflector according to an embodiment of the proposed technology.

FIG. 9 is a schematic illustration of an example of an alternative thin film reflector according to an embodiment of the proposed technology.

FIG. 10 is a schematic illustration of yet another example of a thin film reflector according to an embodiment of the proposed technology.

### DETAILED DESCRIPTION

Throughout the drawings, the same reference designations are used for similar or corresponding elements.

For a better understanding of the proposed technology, it may be useful to begin with a brief overview of potential uses and applications of thin film reflectors according to the proposed technology.

By way of example, a thin film reflector according to any of the disclosed embodiments could be used as part of a high temperature lamp.

According to another example, a thin film reflector as described in any of the embodiments could be used as part of a scintillator for X-ray applications. The thin film reflector provides reflection functionalities for reflecting secondary photons in a scintillator in this application. Since the proposed thin film reflector possesses excellent heat resistant properties it will withstand degrading due to excessive heat applied during the manufacturing stage of the scintillator and/or the heat impact that arises during use of the scintillator in, for example, X-ray applications.

A thin film reflector as described in any of the embodiment might also be used as part of a laser system, e.g. for use as a laser reflector.

A thin film reflector as described in any of the embodiment could also be used as part of optical or electro-optical devices, e.g. for use in space applications.

It may also be useful to provide a general introduction to Atomic Layer Deposition, ALD, techniques and corresponding ALD machines, also referred to as ALD systems.

As the name implies, Atomic Layer Deposition, ALD, generally involves deposition of materials) on the level of atomic layers, and more specifically relates to a thin film deposition technique based on sequential use of one or more gas phase chemical processes. By way of example, ALD includes growing thin films by exposing a substrate to two or more reactive vapors sequentially. This includes but is not limited to regular pulsing of vapors into inert gas flow and purging in between, as well as moving the substrates between spatially separated inert gas zones; also known as Spatial ALD. Reactive vapors can be also generated using a plasma generator to perform Plasma Enhanced ALD, PEALD. The ALD method is also known as atomic layer epitaxy, atomic layer chemical vapor deposition, molecular layering deposition, and molecular layering. More details on the method can be found in the references [1-3] by Suntola et al.

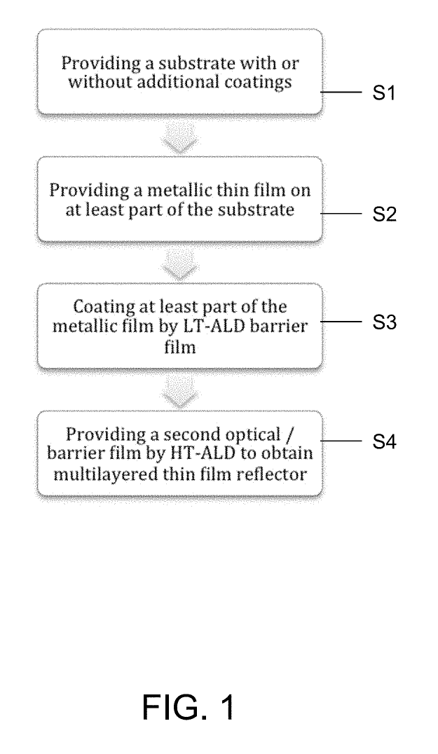

FIG. 1 is a schematic flow diagram illustrating an example of a method for producing a thin film reflector according to an embodiment of the proposed technology. The method comprises the steps of:
providing a substrate comprising at least one type of material;
providing a thin film including a metallic compound on at least part of the substrate;
coating at least part of the thin film with a first barrier layer by applying Low Temperature Atomic Layer Deposition, LT-ALD, with at least one first material, and
providing a second barrier layer on at least part of the first barrier layer by applying High Temperature Atomic Layer Deposition, HT-ALD, with at least one second material to thereby obtain a multi-layered thin film reflector.

The substrate is provided for easier handling of the thin film reflector and it can be e.g. a silicon wafer, a glass window, a metal foil or plate, or some other mechanical structure. In one exemplary embodiment, the substrate may include micro- or macro-scale optical or mechanical structures. The substrate can also include a set of one or more thin film coatings to prevent reactions between the successive thin film reflector layers and the substrate, and to improve the adhesion of the metallic layer to the substrate.

According to an exemplary embodiment of the proposed method there is provided a method wherein the substrate includes a set of one or more thin film coatings. Another possible embodiment provides a method wherein the substrate, instead of a set of thin film coatings, includes surface modifications. In yet another embodiment, both the thin film coatings and surface modifications are included. The substrate chemistry may for example be altered by a plasma/chemical treatment. Particular surface modifications may moreover include e.g. roughening of the substrate surface, native oxide removal, etching or chemical conversion.

These coatings or surface modifications are provided in order to prevent reactions between successive thin film reflector layers and the substrate, and also in order to improve the adhesion of the metallic layer to the substrate.

The metallic thin film might in one particular embodiment of the method for producing a thin film reflector be a compound chosen from Al, Ag, Au or alloys thereof. As such it may be an alloy comprising any of the proposed compounds Al, Ag, Au. It is also possible to use Cu as a compound or even alloys comprising Cu. In another exemplary embodiment, it may be preferable to further treat the metallic thin film with heat, plasma or a layer of optically non-significant material like thin metal, metal oxide, metal nitride or any other thin coating before the first ALD step. In particular embodiments, the thin film may thus be seen as a thin film stack.

The thin film may also be referred to as a reflective thin film, and the first and second barrier layers may also be referred to as protective layers.

The first barrier layer provided by means of LT-ALD, normally constitutes a first protective structure for the reflective metallic thin film. Protecting the metallic thin film in this way opens the way for applying a second barrier layer by means of HT-ALD. By utilizing HT-ALD, a denser and more damage-resistant layer structure is obtained that provides excellent protective features with regard to mechanical, thermal and/or chemical damages. Applying HT-ALD directly on a metallic thin film might however damage the thin film structurally which in turn could affect the reflective features of the thin film negatively.

The deposition temperature in case of atomic layer deposition can mean either the temperature of the substrate or the substrate-holding chamber during the deposition, both of which are usually held at about the same temperature. ALD is typically performed at lower deposition temperatures than chemical vapor deposition processes and the deposition temperatures are typically between 80° C. and 500° C. For that reason, deposition temperatures of roughly less than 200° C. are sometimes referred to as “low temperatures” and deposition temperatures higher than roughly 200° C. as “high temperatures”.

Atomic layer deposition system can perform the growth of thin films in one or many of the previously mentioned ways. The temperatures of different parts of the system can often be varied using the control software or with a separate temperature controller. The ALD steps having a different deposition temperature are often done in separate ALD tools to minimize the negative effects of ramping•temperature of the system up and down. Thus, a multi-temperature process can be performed either in a single deposition unit or by transferring the substrates (and sometimes also the substrate holding reaction chamber) to a separate deposition unit between the steps.

In a particular embodiment of the method for producing a thin film reflector, the first barrier layer is provided by using LT-ALD at a temperature preferably between 0 and 200 degrees Celsius, or between 0 and around 200 degrees Celsius, and more preferably at a temperature between 100 and 150° C., or between around 100 and around 150° C.

The method for producing a thin film reflector might also comprise providing the second barrier layer by using HT-ALD with a temperature above 200 degrees Celsius, or a temperature above around 200 degrees Celsius.

In trials, silver films, for example, start losing their reflectivity if ALD is performed on them above roughly 150-200° C. temperatures. For example, silver films on silicon substrates lose their reflectivity when ALD of Al₂O₃ and TiO2 is applied on them at 300-400° C. However, we have found that if the silver film is first protected with an ALD layer of for example Al₂O₃ grown using trimethylaluminum+water process at low 100-150° C. temperature, the silver film keeps its reflectivity also when further processed at higher temperatures such as >300° C. Thus, it would be beneficial to grow the initial ALD barrier on a thin film including e.g. silver using LT-ALD at 50-200° C., and more preferably at 100-150° C. A person skilled in the art would realize that other metals can have different optimal temperatures and would thus implement the alterations needed to enable use of such metals.

The purity, the chemical and temperature resistance, and other parameters of ALD films are often better when the growth is performed at a higher temperature. For example, ALD-TiO₂ grown using titanium tetrachloride+water process at 300-500° C. is multi-crystalline (with a mixture of anatase and rutile phases depending on the temperature) and very stable against heating and liquid chemicals, whereas ALD-TiO₂ grown at around 100° C. is amorphous, has a higher chlorine content, and has tendency to change phase when heated to above 300° C. Thus, it is preferable to use TiO₂ made using HT-ALD if a high temperature chemical barrier is needed. The same applies to many other ALD films as well, and there are many more ALD process options at 200-400° C. than below 200° C. For these reasons, the barrier stack is preferably at least partly grown at a higher processing temperature.

A particular example embodiment provides a method for producing a thin film reflector wherein the first set of at least one material for LT-ALD and the second set of at least one material for HT-ALD are metal oxides.

Another particular example embodiment provides a method for producing a thin film reflector wherein the materials for the first barrier layer is chosen from the group comprising Al₂O₃, SiO₂, TiO₂, HfO₂, Z₁₀₂, Nb₂O₅, MgO, ZnO, ZnS, Ta₂O₅ or Si₃N₄, and wherein the materials for the second barrier layer is chosen from the group comprising Al₂O₃, AlN, TiO₂, HfO₂, ZrO₂, SiO₂, Nb₂O₅, MgO, ZnO, ZnS, Ta₂O₅ or Si₃N₄. Here, an in what follows, AlN refers to aluminum nitride.

By way of example, the material(s) of the first LT-applied barrier layer may be the same as the material(s) of the HT-applied second barrier layer. In particular embodiments, however, the material(s) of the first barrier layer may differ from the material(s) of the second barrier layer.

In one exemplary embodiment of the method for producing a thin film reflector, the step of coating at least part of the metallic thin film with a first barrier layer, may include the step of providing the first barrier layer with a thickness between 0 and 500 nm, preferably between 0 and 100 nm, more preferably between 25 and 75 nm and even more preferably with a thickness of approximately 50 nm.

In a particular embodiment, the step of coating at least part of the metallic thin film with a first barrier layer by applying Low Temperature Atomic Layer Deposition, LT-ALD, with at least one first material may include the step of coating the metallic thin film with two or more sub-layers of different materials. That is, LT-ALD with a first material may be used to apply an initial sub-layer. LT-ALD is then used with another material to apply a further sub-layer. This can be done for as many sub-layers as desired. In a particular embodiment, this step includes applying an intermediate sub-layer interspersed between adjacent sub-layers.

In yet another particular embodiment, the step of providing a second barrier layer on at least part of the first barrier layer by applying High Temperature Atomic Layer Deposition, HT-ALD, with at least one second material may include the step of coating at least part of the first barrier layer with several sub-layers of different materials. That is, HT-ALD with an initial material is used to apply a first HT-ALD applied sub-layer. HT-ALD is then used with another material to apply a further HT-ALD applied sub-layer. This can be done for as many sub-layers as desired. In a particular embodiment, this step includes applying an intermediate sub-layer interspersed between adjacent sub-layers by means of HT-ALD.

The intermediate layer could be a rather thin layer comprising a few particle layers or atomic layers. By way of example, the material of the intermediate sub-layer is normally different compared to the material of the adjacent sub-layers.

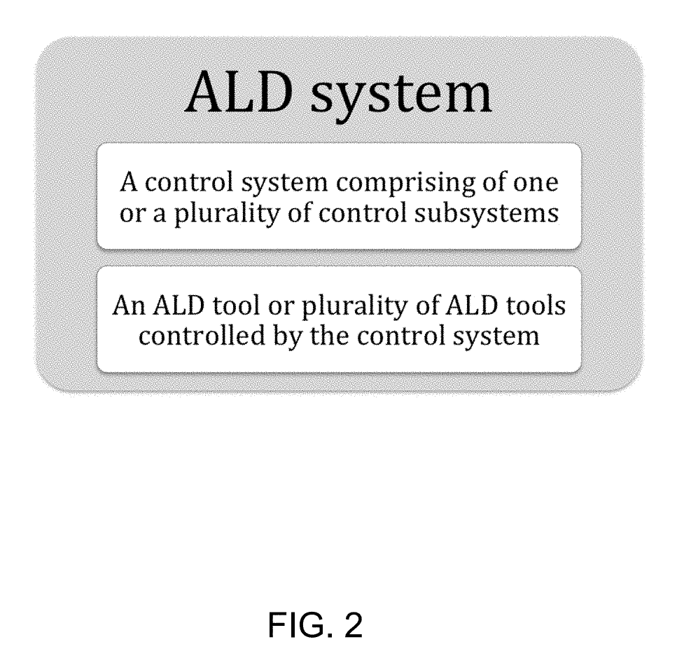

FIG. 2 is a schematic block diagram illustrating an example of an Atomic Layer Deposition, ALD, system for producing a thin film reflector. The ALD system comprises:
a control system comprising one or a plurality of control subsystems, and
at least one ALD tool controlled by the control system,
wherein an ALD tool is configured to provide a first barrier layer on at least part of a thin film including a metallic compound by applying Low Temperature ALD, LT-ALD, with at least one first material, and
wherein an ALD tool is configured to provide a second barrier layer on at least part of the first barrier layer by applying High Temperature ALD, HT-ALD, with at least one second material, to thereby obtain a multi-layered thin film reflector.

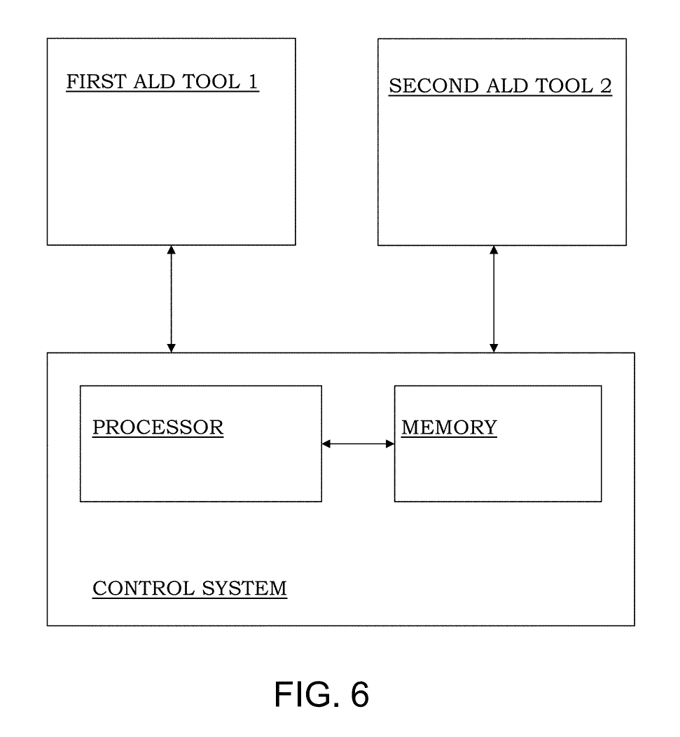

An alternative example of an ALD system is illustrated in FIG. 6. In the example of FIG. 6, there is shown two different ALD tools, a first ALD tool 1 and a second ALD tool 2. The first and second ALD tools are preferably controlled by a common control system. The first ALD tool might be dedicated to perform Low Temperature ALD, LT-ALD, with a first set of at least one material and the second ALD tool might be dedicated to perform High Temperature ALD, HT-ALD, with a second set of at least one material. The ALD system might in other words comprise several ALD tools, including a first ALD tool 1 and a second ALD tool 2. The different ALD tools may be controlled by a common control system and might be dedicated, or adapted, to perform different operations such as LT-ALD and HT-ALD, respectively.

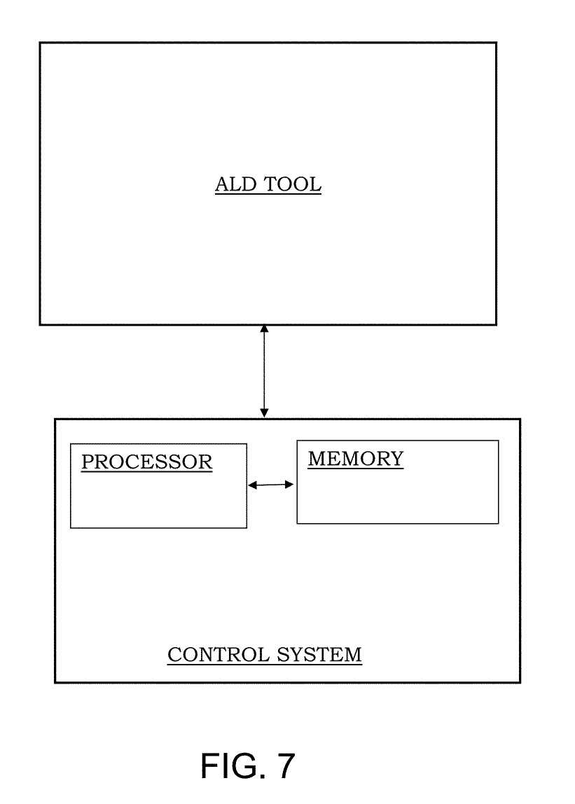

It should be noted that the first ALD tool might be the same as the second ALD tool in particular embodiments. In effect, this means that one and the same ALD tool is adapted to perform the LT-ALD and HT-ALD processes. Such a system is shown in FIG. 7. In other embodiments it might however be preferred to have more than one ALD tool, or even more than two ALD tools. That is, the system might comprise several different ALD tools, each being adapted to perform specific operations. This feature applies for all the described embodiments of the ALD system.

One particular example embodiment provides an ALD system wherein the control system is configured to control the temperature at which an ALD tool applies the first barrier layer during LT-ALD, and to control the temperature at which the same, or a different, ALD tool applies the second barrier layer during HT-ALD, e.g. as previously discussed in relation to the above-described embodiments of the manufacturing method.

Another embodiment provides an ALD system wherein the control system is further configured to control an ALD tool to provide the first barrier layer with a specified thickness, e.g. as previously discussed.

Yet another embodiment provides an ALD system wherein the control system is further configured to control an ALD tool to provide the second barrier layer with a specified thickness, e.g. as previously discussed.

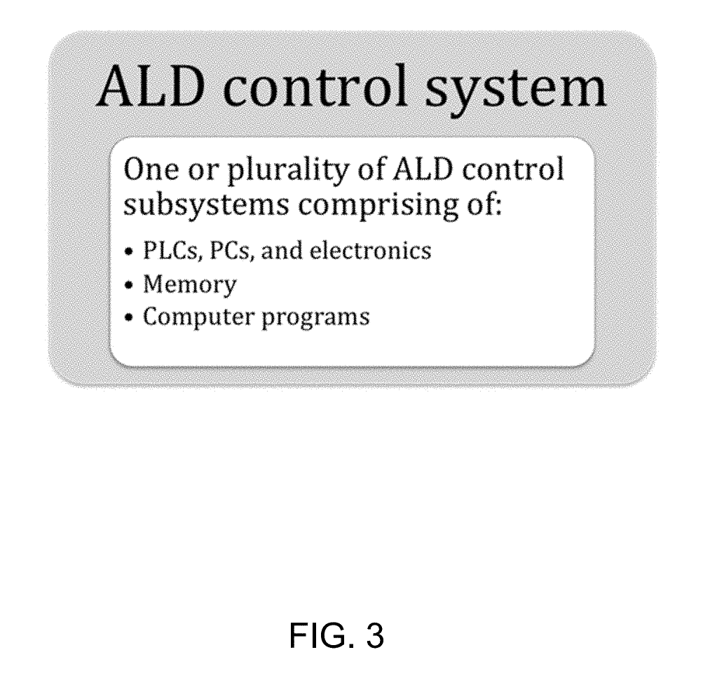

FIG. 3 is a schematic block diagram illustrating an example of an ALD control system configured to control an Atomic Layer Deposition, ALD, system,
wherein the control system is configured to control at least a first temperature at which an ALD tool shall apply Low Temperature ALD, LT-ALD, with at least one first material on at least part of a thin film including a metallic compound to at least partially coat the thin film with a first barrier layer, and
wherein the control system is configured to control at least a second temperature at which an ALD tool shall apply High Temperature ALD, HT-ALD, with at least one second material on at least part of the first barrier layer to at least partially coat the first barrier layer with a second barrier layer, to thereby obtain a multi-layered thin film reflector.

In an illustrative example embodiment the control system might be implemented as a Programmable Logic Controller.

In a particular embodiment the control system comprises a memory and a processor, the memory comprising instructions executable by the processor wherein the control system is operative to control the ALD machine.

In an exemplary embodiment, the control system is configured to set the first temperature in the range of 0-200 degrees Celsius, or in the range of around 0 to around 200 degrees Celsius.

In another exemplary embodiment, the control system is configured to set the second temperature to above 200 degrees Celsius, or to above around 200 degrees Celsius.

Other temperature intervals have been discussed above.

A control system according to a particular embodiment might further be configured to set a first thickness level that determines the thickness of the first barrier layer.

A control system according to an exemplary embodiment might further be configured to set another thickness level that determines the thickness of the second barrier layer.

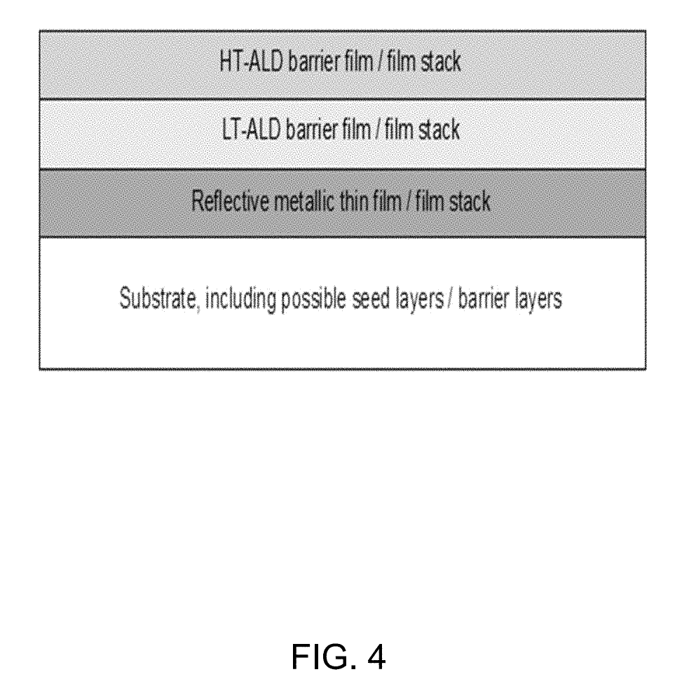

FIG. 4 schematically illustrates an example of a thin film reflector comprising:
a substrate comprising at least one type of material;
a thin film or a thin film stack including a metallic compound provided on at least part of the substrate;
a first barrier layer provided on at least part of the thin film by means of Low Temperature Atomic Layer Deposition, LT-ALD, of at least one first material, and
a second barrier layer provided on at least part of the first barrier layer by means of High Temperature Atomic Layer Deposition, HT-ALD, of at least one second material.

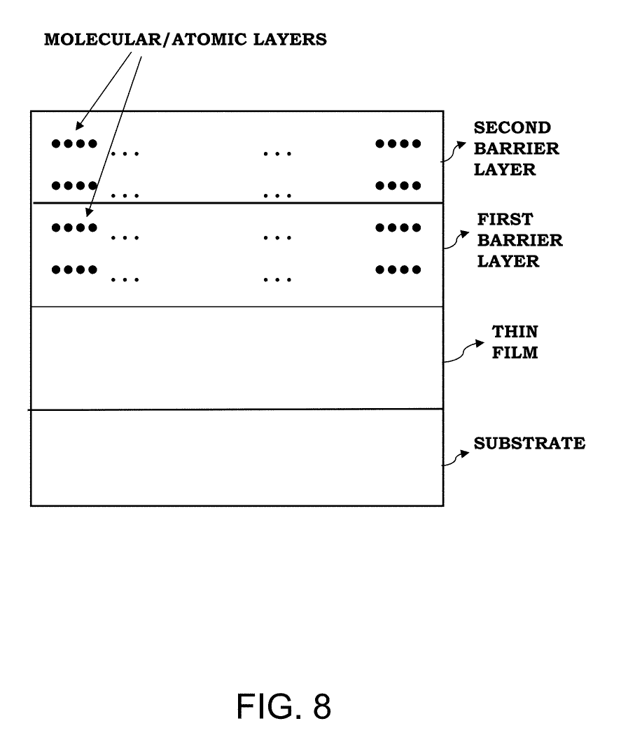

FIG. 8 is a schematic diagram illustrating a slightly different representation of the thin film reflector.

The substrate is provided for easier handling of the thin film reflector and it can be e.g. a silicon wafer, a glass window, a metal foil or plate, or some other mechanical structure. In one exemplary embodiment, the substrate may include micro- or macro-scale optical or mechanical structures. The substrate can also include a set of one or more thin film coatings to prevent reactions between the successive thin film reflector layers and the substrate, and to improve the adhesion of the metallic layer to the substrate. The same purpose can be achieved if surface modifications are provided on the substrate instead of a set of one or more thin film coatings. In some cases, both the thin film coatings and surface modifications can be used. The substrate chemistry may for example be altered by a plasma/chemical treatment. Particular surface modifications may moreover include e.g. roughening of the surface, native oxide removal, etching and chemical conversion.

A particular embodiment of the thin film reflector provides a thin film reflector wherein the metallic compound of the thin film base is a compound chosen from Al, Ag, Au or alloys thereof, or alloys comprising any of the proposed compounds. It is also possible to use Cu or alloys comprising Cu as a compound.

As an example, the first barrier layer may actually be grown more or less particle for particle by means of LT-ALD. The first barrier layer could thus be seen as being composed of a stack of molecular or atomic layers. FIG. 8 illustrates this particular feature. The first barrier layer might also comprise several sub-layers. Each of these sub-layers could be provided by Low Temperature Atomic Layer Deposition, LT-ALD, with different materials. In other words, a first sub-layer 1 might comprise one material while a second sub-layer 2, and upwards with more layers if desired, could comprise different material(s).

In another particular embodiment of a thin film reflector according to the proposed technology, the first barrier layer may comprise two different sub-layers, a first LT-ALD applied protective sub-layer 1 and a second LT-ALD applied protective sub-layer 2.

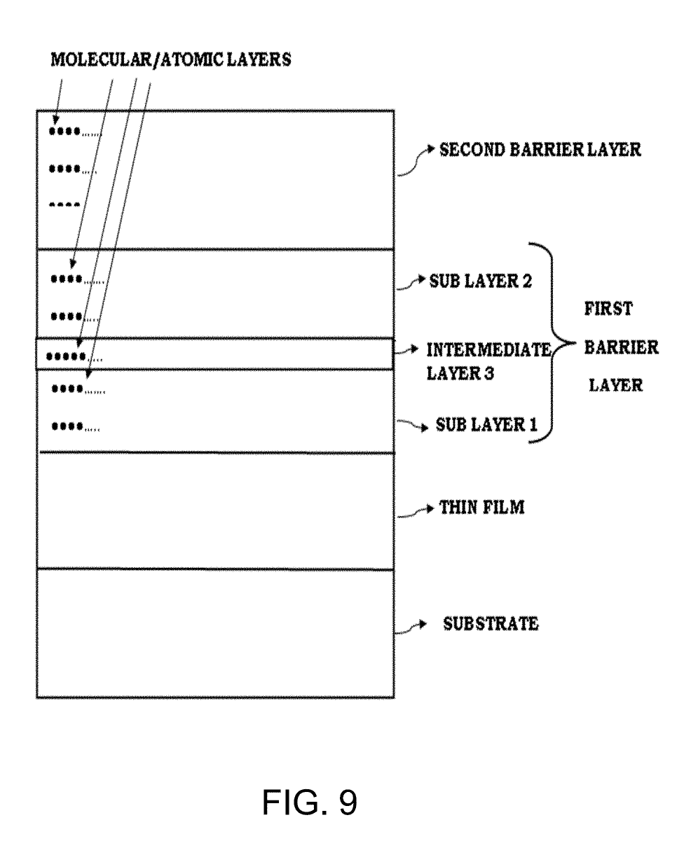

By way of example, the first barrier layer might also comprise an intermediate layer 3 that is embedded between the first protective sub-layer 1 and the second protective sub-layer 2, as illustrated in FIG. 9. One particular purpose of the intermediate layer is to prevent cracks originating in the first barrier layer to propagate all the way down to the metallic thin film. This will ensure that the metallic thin film is satisfactorily protected from structural damages. The intermediate layer 3 should also be provided by means of LT-ALD. The first protective sub-layer 1 could in this particular embodiment comprise the same material as the second protective sub-layer 2. The intermediate layer 3 might however comprise a different set of one or more materials.

The first barrier layer provided by means of LT-ALD, normally constitutes a first protective structure for the reflective metallic thin film. By protecting the metallic thin film in this way it opens the way for applying a second barrier layer by means of HT-ALD. By utilizing HT-ALD a denser and more damage resistant layer structure is obtained that provides excellent protective features with regard to mechanical, thermal and/or chemical damages. Applying HT-ALD directly on a metallic thin film might however damage the thin film structurally which in turn could affect the reflective features of the thin film negatively.

The second barrier layer could also be grown more or less particle for particle, but this time by means of HT-ALD. The second barrier layer can also be seen as being composed of a stack of molecular or atomic layers.

By way of example, the second barrier layer may also comprise two or more sub-layers. Each of these sub-layers could be provided by High Temperature Atomic Layer Deposition, HT-ALD, with a different set of materials. In other words, one sub-layer may comprise a given material while another sub-layer may comprise a different material.

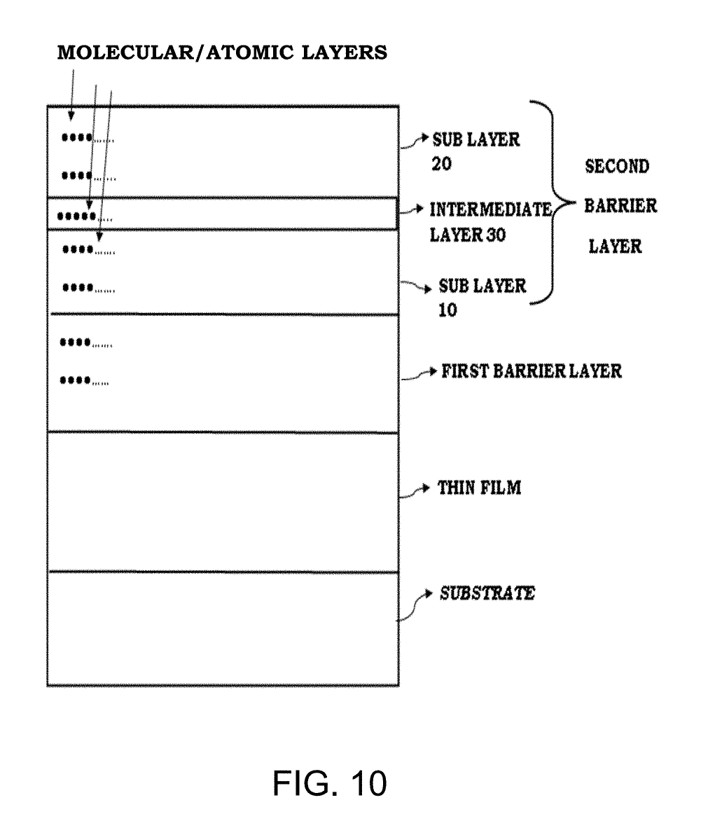

In another particular embodiment of a thin film reflector according to the proposed technology, the second barrier layer could comprise two different sub-layers, an HT-ALD applied first protective sub-layer 10 and an HT-ALD applied second protective sub-layer 20. The second barrier layer might also comprise an intermediate layer 30 that is embedded between the first protective sub-layer 10 and the second protective sub-layer 20, as illustrated schematically in FIG. 10.

One particular purpose of the intermediate layer is to prevent cracks originating in the second barrier layer to propagate all the way down to the metallic thin film. This will ensure that the metallic thin film is satisfactorily protected from structural damages. The intermediate layer 30 should also be provided by means of LT-ALD. The first protective sub-layer 10 could in this particular embodiment comprise the same material as the second protective sub-layer 20. The intermediate layer 30 might however comprise a different set of one or more materials.

Example embodiments include a thin film reflector wherein the thickness of the first barrier layer lies between 0 and 500 nm, preferably between 0 and 100 nm, more preferably between 25 and 75 nm and even more preferably with a thickness of approximately 50 nm.

Still another example of an embodiment of a thin film reflector provides a thin film reflector wherein the first set of at least one material for LT-ALD and the second set of at least one material for HT-ALD are metal oxides.

An illustrative, though exemplary, embodiment of a thin film reflector discloses a thin film reflector wherein the first barrier layer includes at least one material chosen from the group comprising Al₂O₃, SiO₂, TiO₂, HfO₂, ZrO₂, Ta₂O₅, Nb₂O₅, MgO, ZnO, ZnS, Ta₂O₅, Si₃N₄. The second barrier layer includes at least one material chosen from the group comprising Al₂O₃, AlN, TiO₂, HfO₂, ZrO₂, SiO₂, Si₃N₄, Ta₂O₅, Nb₂O₅, MgO, ZnO, ZnS, Ta₂O₅ or Si₃N₄.

Optionally, suitable material(s) for the barrier layer(s) include at least one oxide and/or nitride selected from Groups IVB, VB, VIB, IIIA, and IVA of the Periodic Table or combinations thereof.

A thin film reflector according to any of the earlier described embodiments could be used as part of a high temperature lamp.

A thin film reflector as described in any of the earlier embodiments could be used as part of a scintillator for X-ray applications. The thin film reflector provides reflection functionalities for reflecting secondary photons in a scintillator in this application. Since the proposed thin film reflector possesses excellent heat resistant features it will withstand degrading due to excessive heat applied during the manufacturing stage of the scintillator as well as the heat impact that arises during use of the scintillator in, for example, X-ray applications.

A thin film reflector as described in any of the embodiment might also be used as part of a laser system, e.g. for use as a laser reflector.

A thin film reflector as described in any of the embodiment could also be used as part of optical or electro-optical devices, e.g. for use in space applications.

The proposed technology also provides a computer program comprising instructions which, when executed on at least one processor, cause the at least one processor to:
control at least a first temperature at which an ALD tool shall apply Low Temperature ALD, LT-ALD, with at least one first material to coat at least part of a thin film including a metallic compound with a first barrier layer;
control at least a second temperature at which an ALD tool shall apply High Temperature ALD, HT-ALD, with at least one second material on at least part of the first barrier layer to coat at least part of the first barrier layer with a second barrier layer to thereby obtain a multi-layered thin film reflector.

It will be appreciated that the methods and devices described herein can be combined and re-arranged in a variety of ways.

For example, embodiments may be implemented in hardware, or in software for execution by suitable processing circuitry, or a combination thereof.

The steps, functions, procedures, modules and/or blocks described herein may be implemented in hardware using any conventional technology, such as discrete circuit or integrated circuit technology, including both general-purpose electronic circuitry and application-specific circuitry.

Particular examples include one or more suitably configured digital signal processors and other known electronic circuits, e.g. discrete logic gates interconnected to perform a specialized function, or Application Specific Integrated Circuits (ASICs).

Alternatively, at least some of the steps, functions, procedures, modules and/or blocks described herein may be implemented in software such as a computer program for execution by suitable processing circuitry such as one or more processors or processing units.

The flow diagram or diagrams presented herein may therefore be regarded as a computer flow diagram or diagrams, when performed by one or more processors. A corresponding apparatus may be defined as a group of function modules, where each step performed by the processor corresponds to a function module. In this case, the function modules are implemented as a computer program running on the processor.

Examples of processing circuitry includes, but is not limited to, one or more microprocessors, one or more Digital Signal Processors, DSPs, one or more Central Processing Units, CPUs, video acceleration hardware, and/or any suitable programmable logic circuitry such as one or more Field Programmable Gate Arrays, FPGAs, or one or more Programmable Logic Controllers, PLCs.

It should also be understood that it may be possible to re-use the general processing capabilities of any conventional device or unit in which the proposed technology is implemented. It may also be possible to re-use existing software, e.g. by reprogramming of the existing software or by adding new software components.

In a particular example, at least some of the steps, functions, procedures, modules and/or blocks described herein are implemented in a computer program, which is loaded into the memory for execution by the processing circuitry.

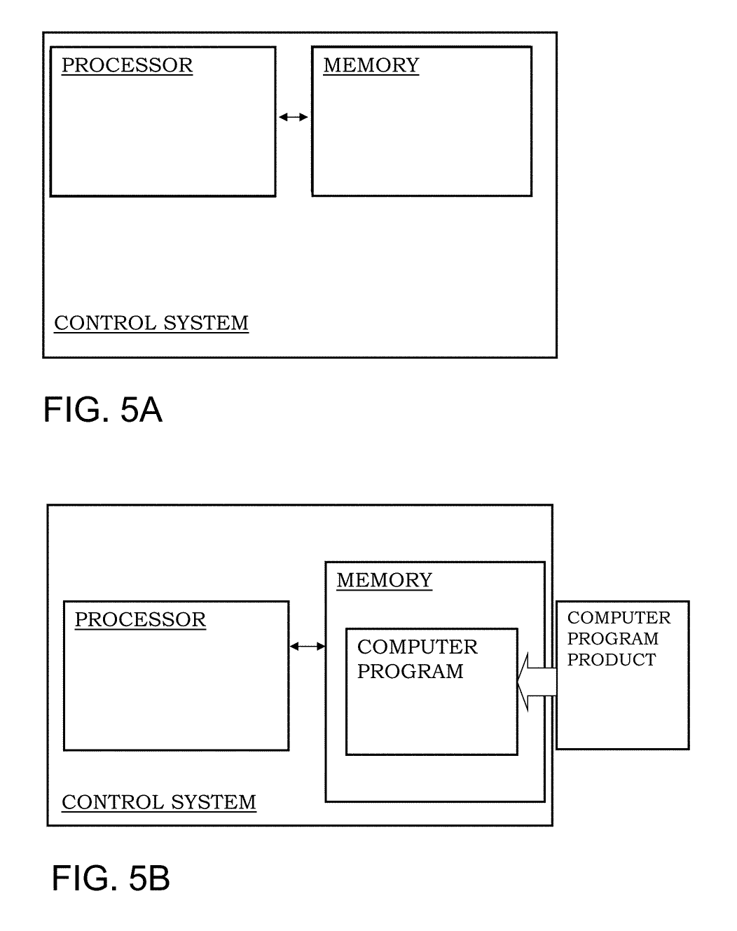

FIG. 5A is a schematic block diagram illustrating an example of a control system comprising processing circuitry such as one or more processors, and a memory and an optional interface.

The processing circuitry and memory are interconnected to each other to enable normal software execution. An optional input/output device may also be interconnected to the processing circuitry and/or the memory to enable input and/or output of relevant data such as input parameter(s) and/or resulting output parameter(s).

The term ‘processing circuitry’ or ‘processor’ should be interpreted in a general sense as any system or device capable of executing program code or instructions to perform a particular processing, determining or computing task.

FIG. 5B illustrates the use of a computer program in a control system according to the proposed technology.

In particular, the software or computer program may be realized as a computer program product, which is normally carried or stored on a computer-readable medium. The computer-readable medium may include one or more removable or non-removable memory devices including, but not limited to a Read-Only Memory, ROM, a Random Access Memory, RAM, a Compact Disc, CD, a Digital Versatile Disc, DVD, a Universal Serial Bus, USB, memory, a Hard Disk Drive, HDD storage device, a flash memory, or any other conventional memory device. The computer program may thus be loaded into the operating memory of a computer or equivalent processing device for execution by the processing circuitry thereof.

For example, the computer program stored in memory includes program instructions executable by the processing circuitry, whereby the processing circuitry is able or operative to execute the above-described steps, functions, procedure and/or blocks.

The computer or processing circuitry does not have to be dedicated to only execute the above-described steps, functions, procedure and/or blocks, but may also execute other tasks.

The embodiments described above are merely given as examples, and it should be understood that the proposed technology is not limited thereto. It will be understood by those skilled in the art that various modifications, combinations and changes may be made to the embodiments without departing from the present scope as defined by the appended claims. In particular, different part solutions in the different embodiments can be combined in other configurations, where technically possible.

### REFERENCES

[1] U.S. Pat. No. 4,058,430.
[2] U.S. Pat. No. 4,389,973.
[3] U.S. Pat. No. 4,413,022.
[4] European Patent 1 994 202 B1.

1-46. (canceled)

47. A method for producing a thin film reflector, wherein the method comprises the steps of:
providing (S1) a substrate comprising at least one type of material;
providing (S2) a thin film including a metallic compound on at least part of said substrate;
coating (S3) at least part of said thin film with a first barrier layer by applying Low Temperature Atomic Layer Deposition, LT-ALD, with at least one first material; and
providing (S4) a second barrier layer on at least part of said first barrier layer by applying High Temperature Atomic Layer Deposition, HT-ALD, with at least one second material to thereby obtain a multi-layered thin film reflector.

48. The method according to claim 47, wherein said substrate includes a set of one or more thin film coatings, and/or surface modifications, in order to prevent reactions between successive thin film reflector layers and said substrate, and in order to improve the adhesion of the metallic layer to said substrate.

49. The method according to claim 47, wherein the metallic compound included in said thin film comprises a compound chosen from Al, Ag, Au, Cu or alloys thereof or alloys comprising any of said compounds.

50. The method according to claim 47, wherein the method further comprises preparing said thin film with heat, plasma or a layer of optically non-significant material such as a thin metal, a metal oxide, a metal nitride or any other thin coating before said LT-ALD step is performed.

51. The method according to claim 47, wherein said first barrier layer is provided by using LT-ALD at a temperature preferably between 0 and around 200 degrees Celsius, and more preferably at a temperature between around 100 and around 150° C.

52. The method according to claim 47, wherein the second barrier layer is provided by using HT-ALD with a temperature above around 200 degrees Celsius.

53. The method according to claim 47, wherein said first set of at least one material for LT-ALD and said second set of at least one material for HT-ALD are metal oxides.

54. The method according to claim 47, wherein the materials for the first barrier layer is chosen from the group comprising Al₂O₃, SiO₂, TiO₂, HfO₂, ZrO₂, Nb₂O₅, MgO, ZnO, ZnS, Ta₂O₅, Si₃N₄, and wherein the materials for the second barrier layer is chosen from the group comprising Al₂O₃, AlN, TiO₂, HfO₂, ZrO₂, SiO₂, Nb₂O₅, MgO, ZnO, ZnS, Ta₂O₅ or Si₃N₄.

55. The method according to claim 47, wherein the step (S3) of coating at least part of the metallic thin film with a first barrier layer, includes providing the first barrier layer with a thickness between 0 and 500 nm, preferably between 0 and 100 nm, more preferably between 25 and 75 nm and even more preferably with a thickness of approximately 50 nm.

56. Atomic Layer Deposition, ALD, system for producing a thin film reflector, wherein the ALD system comprises:
a control system comprising one or a plurality of control subsystems; and
at least one ALD tool controlled by the control system;
wherein an ALD tool is configured to provide a first barrier layer on at least part of a thin film including a metallic compound by applying Low Temperature ALD, LT-ALD, with at least one first material; and
wherein an ALD tool is configured to provide a second barrier layer on at least part of the first barrier layer by applying High Temperature ALD, HT-ALD, with at least one second material, to thereby obtain a multi-layered thin film reflector.

57. The ALD system according to claim 56, wherein the ALD system comprises several ALD tools, including a first ALD tool (1) and a second ALD tool (2).

58. The ALD system according to claim 57, wherein the system comprises two different ALD tools, a first ALD tool (1) and a second ALD tool (2), said first and second ALD tools are preferably controlled by a common control system, said first ALD tool being adapted to perform Low Temperature ALD, LT-ALD, with a first set of at least one material and the second ALD tool being adapted to perform High Temperature ALD, HT-ALD, with a second set of at least one material.

59. An ALD control system configured to control an Atomic Layer Deposition, ALD, system,
wherein the control system is configured to control at least a first temperature at which an ALD tool shall apply Low Temperature ALD, LT-ALD, with at least one first material on at least part of a thin film including a metallic compound to at least partially coat the thin film with a first barrier layer; and
wherein the control system is configured to control at least a second temperature at which an ALD tool shall apply High Temperature ALD, HT-ALD, with at least one second material on at least part of the first barrier layer to at least partially coat the first barrier layer with a second barrier layer, to thereby obtain a multi-layered thin film reflector.

60. A thin film reflector comprising:
a substrate comprising at least one type of material: a thin film or a thin film stack including a metallic compound provided on at least part of the substrate;
a first barrier layer provided on at least part of the thin film by means of Low Temperature Atomic Layer Deposition, LT-ALD, of at least one first material; and
a second barrier layer provided on at least part of the first barrier layer by means of High Temperature Atomic Layer Deposition, HT-ALD, of at least one second material.

61. A computer program product comprising a non-transitory computer-readable storage having stored thereon a computer program, wherein the computer program comprises instructions which, when executed on at least one processor, cause the at least one processor to:
control at least a first temperature at which an ALD tool shall apply Low Temperature ALD, LT-ALD, with at least one first material to coat at least part of a thin film including a metallic compound with a first barrier layer;
control at least a second temperature at which an ALD tool shall apply High Temperature ALD, HT-ALD, with at least one second material on at least part of the first barrier layer to coat at least part of the first barrier layer with a second barrier layer to thereby obtain a multi-layered thin film reflector.

62. The method according to claim 48, wherein the metallic compound included in said thin film comprises a compound chosen from Al, Ag, Au, Cu or alloys thereof or alloys comprising any of said compounds.

63. The method according to claim 48, wherein the method further comprises preparing said thin film with heat, plasma or a layer of optically non-significant material such as a thin metal, a metal oxide, a metal nitride or any other thin coating before said LT-ALD step is performed.

64. The method according to claim 49, wherein the method further comprises preparing said thin film with heat, plasma or a layer of optically non-significant material such as a thin metal, a metal oxide, a metal nitride or any other thin coating before said LT-ALD step is performed

65. The method according to claim 48, wherein said first barrier layer is provided by using LT-ALD at a temperature preferably between 0 and around 200 degrees Celsius, and more preferably at a temperature between around 100 and around 150° C.

66. The method according to claim 49, wherein said first barrier layer is provided by using LT-ALD at a temperature preferably between 0 and around 200 degrees Celsius, and more preferably at a temperature between around 100 and around 150° C.
